(19) United States
(12) Patent Application Publication
(10) Pub. No.: US 2026/0305416 A1
(43) Pub. Date: Oct. 1, 2026

(54) POWER MODULE

(71) Applicant: Mitsubishi Electric Corporation, Tokyo (JP)

(72) Inventors: Yasushige MUKUNOKI, Tokyo (JP); Yoshiko TAMADA, Tokyo (JP)

(73) Assignee: Mitsubishi Electric Corporation, Tokyo (JP)

(21) Appl. No.: 19/478,279

(22) PCT Filed: Nov. 28, 2023
(86) PCT No.: PCT/JP2023/042467

§ 371 Date: Oct. 24, 2025

(30) Foreign Application Priority Data
Apr. 25, 2023 (WO) PCT/JP2023/016276

(51) Int. Cl. H10W 70/654; H10W 90/00; H10W 90/10

(52) U.S. Cl. CPC H10W 70/654; H10W 90/10; H10W 90/754

(57) ABSTRACT

A power module includes first and second conductive patterns, a first power conversion semiconductor element group including power conversion semiconductor elements arranged in a first direction on the first conductive pattern, and wires, wherein a slit is formed in the second conductive pattern, and the second conductive pattern includes first and second partition regions, and wherein M>N/2 and A≥B×M/N are satisfied, where A is a width of the first partition region in a second direction orthogonal to the first direction, B is a width of the second partition region in the second direction, N is a number of the power conversion semiconductor elements constituting the first power conversion semiconductor element group, and M is a number of the power conversion semiconductor elements connected to the first partition region by their respective wires among the first power conversion semiconductor element group.

### TECHNICAL FIELD

The present disclosure relates to a power module.

### BACKGROUND ART

In a power module including a plurality of semiconductor elements connected in parallel, when the magnitude of the current flowing through each of the plurality of semiconductor elements is not uniform, the current may concentrate on some of the semiconductor elements, and the semiconductor elements on which the current concentrates may be damaged.

In order to solve such a problem, a technique is known, in which a slit pattern is introduced into a conductive pattern formed on an insulating substrate, and thus, the impedance from each of the semiconductor elements to an external lead-out terminal is made uniform with high accuracy (Patent Document 1).

### PRIOR ART DOCUMENTS

### Patent Documents

[Patent Document 1] International Publication No. WO2016/009496

### SUMMARY OF THE INVENTION

### Problems to be Solved by the Invention

However, even in the case of the power module in which the slit pattern is introduced into the conductive pattern to reduce the variation among the impedances from each of the semiconductor elements to the external lead-out terminal, as in Patent Document 1, the magnitudes of currents flowing through each of the semiconductor elements may vary.

Specifically, the inventors of the present disclosure found that, in the power transistor module described in Patent Document 1, the magnitude of current flowing through each of the semiconductor elements may vary due to the variation in the temperature distribution of the conductive pattern connected to the semiconductor elements via bonding wires.

The present disclosure is made to solve the above-described problem, and the object thereof is to provide a power module with high reliability in which the current is suppressed from concentrating on some of the semiconductor elements among the plurality of semiconductor elements included in the power module.

### Means for Solving the Problems

A power module according to the present disclosure includes: an insulation member having a main surface; a first conductive pattern and a second conductive pattern formed on the main surface and spaced apart from each other; a first power conversion semiconductor element group including a plurality of power conversion semiconductor elements arranged in a first direction on the first conductive pattern; and a plurality of wires electrically connecting their respective power conversion semiconductor elements constituting the first power conversion semiconductor element group and the second conductive pattern, wherein a slit is formed in the second conductive pattern to lengthen a current path length from each of the power conversion semiconductor elements constituting the first power conversion semiconductor element group to a second external terminal connected to the second conductive pattern, wherein the second conductive pattern includes: a first partition region to which some of the plurality of wires are connected and which is partitioned by the slit; and a second partition region to which wires other than the wires connected to the first partition region among the plurality of wires are connected and which is adjacent to the first partition region, and wherein M>N/2 and a length of A satisfies a relationship of A≥B×M/N, where A is a width of the first partition region in a second direction orthogonal to the first direction, B is a width of the second partition region in the second direction, N is the number of the power conversion semiconductor elements constituting the first power conversion semiconductor element group, and M is the number of the power conversion semiconductor elements connected to the first partition region by their respective wires among the power conversion semiconductor elements constituting the first power conversion semiconductor element group.

A power module according to the present disclosure includes: an insulation member having a main surface; a first conductive pattern and a second conductive pattern formed on the main surface and spaced apart from each other; a first power conversion semiconductor element group including a plurality of power conversion semiconductor elements arranged in a first direction on the first conductive pattern; and a plurality of wires electrically connecting their respective power conversion semiconductor elements constituting the first power conversion semiconductor element group and the second conductive pattern, wherein a slit is formed in the second conductive pattern to lengthen a current path length from each of the power conversion semiconductor elements constituting the first power conversion semiconductor element group to a second external terminal connected to the second conductive pattern, wherein the second conductive pattern includes: a first partition region to which some of the plurality of wires are connected and which is partitioned by the slit; and a second partition region to which wires other than the wires connected to the first partition region among the plurality of wires are connected and which is adjacent to the first partition region, and wherein a size of S1 satisfies a relationship of S1≥S2×{M/(N−M)}, where S1 is an area of the first partition region, S2 is an area of the second partition region, N is the number of the power conversion semiconductor elements constituting the first power conversion semiconductor element group, and M is the number of the power conversion semiconductor elements connected to the first partition region by their respective wires among the power conversion semiconductor elements constituting the first power conversion semiconductor element group.

### Effects of the Invention

According to the power module of the present disclosure, since the current is suppressed from concentrating on some of the semiconductor elements among the plurality of semiconductor elements included in the power module, it is possible to obtain a power module with high reliability.

### BRIEF DESCRIPTION OF THE DRAWINGS

FIG. 1 is a circuit diagram of a power module according to Embodiment 1.

FIG. 2 shows a top view of the power module according to Embodiment 1.

FIG. 3 is a cross-sectional view of the P-P portion shown in FIG. 2.

FIG. 4 is a top view showing an example of a slit shape.

FIG. 5 shows a top view of a power module according to a modification of Embodiment 1.

FIG. 6 shows a top view of a power module according to Embodiment 2.

FIG. 7 is a circuit diagram of a power module according to Embodiment 3.

FIG. 8 shows a top view of the power module according to Embodiment 3.

FIG. 9 shows a top view of a power module according to a modification of Embodiment 3.

### EMBODIMENTS FOR IMPLEMENTING THE INVENTION

Hereinafter, power modules according to the embodiments of the present disclosure will be described with reference to the drawings. The drawings are schematically shown, and the dimensional ratios and the numbers of components in the drawings do not necessarily match the actual dimensional ratios and the actual numbers of components.

In the embodiments of the present disclosure, the description will be made using as an example a case where power conversion semiconductor elements included in the power module are each a pair of an insulated gate bipolar transistor (IGBT) and a freewheeling diode. However, the power conversion semiconductor elements included in the power module are not limited to those elements and may include another type of semiconductor elements such as a metal oxide semiconductor field effect transistor (MOSFET) or a bipolar transistor.

### Embodiment 1

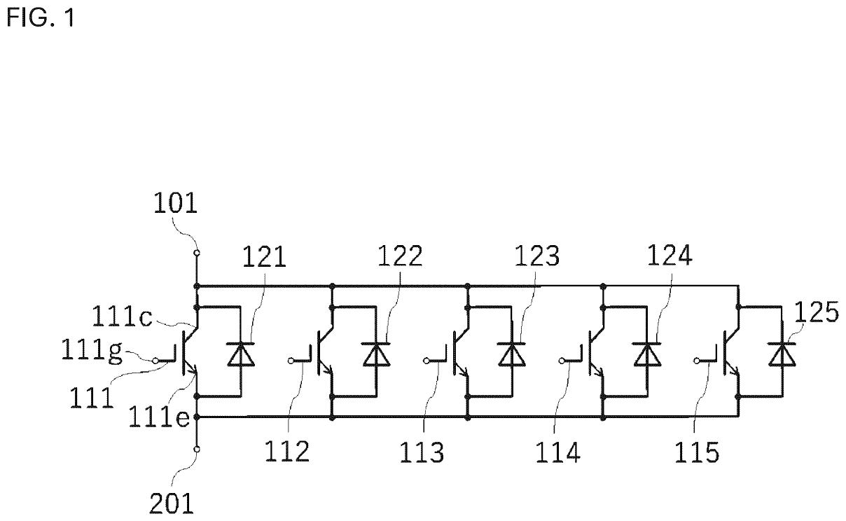

Embodiment 1 will be described on the basis of FIGS. 1 to 3. FIG. 1 is a circuit diagram of a power module according to Embodiment 1 of the present disclosure. FIG. 1 shows a positive electrode 101 of high potential, a negative electrode 201 of low potential, first to fifth IGBTs (111, 112, 113, 114, 115), and first to fifth freewheeling diodes (121, 122, 123, 124, 125).

The first IGBT 111 can switch in conductivity between a collector electrode 111c and an emitter electrode 111e by applying a voltage between a gate electrode 111g and the emitter electrode 111e. When a positive voltage is applied between the gate electrode 111g and the emitter electrode 111e, the resistance between the collector electrode 111c and the emitter electrode 111e becomes low, and the current flows in the direction from the collector electrode 111c to the emitter electrode 111e. On the other hand, when a voltage equal to or lower than 0 V is applied between the gate electrode 111g and the emitter electrode 111e, the resistance between the collector electrode 111c and the emitter electrode 111e becomes high, and the current between the collector electrode 111c and the emitter electrode 111e is blocked. The second to fifth IGBTs (112, 113, 114, 115) also have the same function as the first IGBT 111.

In general, in order to expand the current rating of a power module, a plurality of power conversion semiconductor elements is connected in parallel. That is, the number of power conversion semiconductor elements connected in parallel is appropriately set according to the current rating of the power module. In the present embodiment, a case is exemplified, in which five power conversion semiconductor elements are connected in parallel and thus the current rating is increased five times compared to the case of one power conversion semiconductor element.

The first freewheeling diode 121 is connected in anti-parallel with the first IGBT 111. The first freewheeling diode 121 becomes the conductive path when the current flows in the direction from the emitter electrode 111e to the collector electrode 111c in the first IGBT 111. The second to fifth freewheeling diodes (122, 123, 124, 125) also have the same function as the first freewheeling diode 121.

In general, there is an allowable upper limit temperature for a semiconductor element, and if the semiconductor element is overheated beyond the upper limit temperature, the semiconductor element may be broken. For example, when a current flows intensively through the first IGBT 111, which is one of the first to fifth IGBTs (111, 112, 113, 114, 115) shown in FIG. 1, the first IGBT 111 is overheated due to excessive self-heating, and may be broken. Therefore, it is necessary to reduce the variation among magnitudes of the currents flowing through each of the first to fifth IGBTs (111, 112, 113, 114, 115). In addition, the variation among the magnitudes of the currents flowing through the first to fifth freewheeling diodes (121, 122, 123, 124, 125) also needs to be reduced.

Here, in the present specification, when it is described that the variation among the magnitudes of the currents is reduced, it means that the variation among the magnitudes of the currents flowing through each of the power conversion semiconductor elements is suppressed to the extent that the currents are not concentrated on some of the power conversion semiconductor elements of a power conversion semiconductor element group.

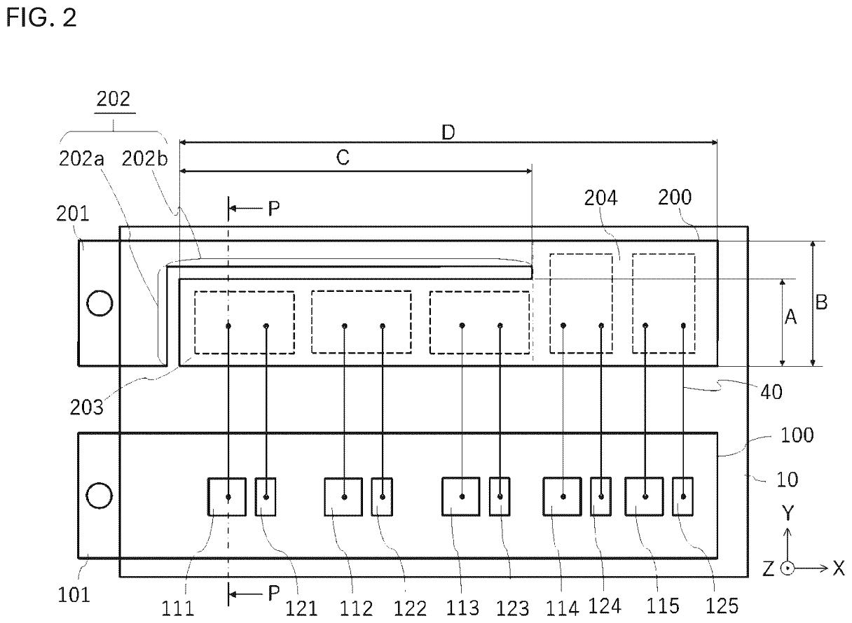

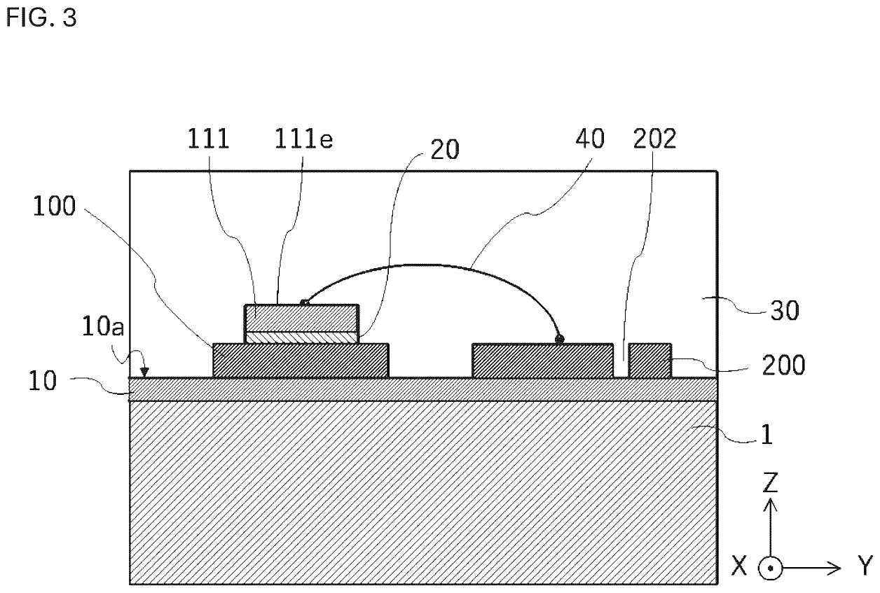

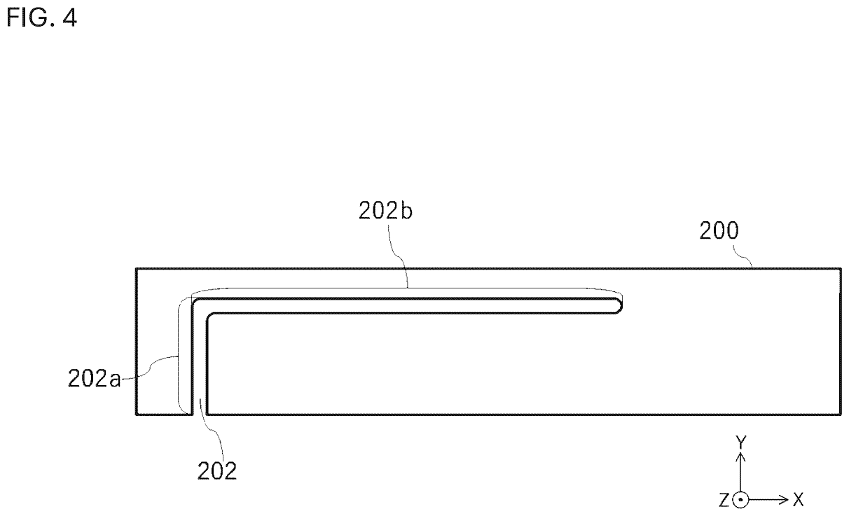

The structure of the power module according to Embodiment 1 will be described with reference to FIGS. 2 to 4. FIG. 2 shows a top view of the power module according to Embodiment 1. FIG. 3 is a cross-sectional view of the P-P portion shown in FIG. 2. FIG. 4 is a top view showing an example of a slit shape formed by machining. For the sake of description, a sealing member 30 is omitted in FIG. 2. In FIG. 3, which is a cross-sectional view, the sealing member 30 is shown as the portion without being hatched.

As shown in FIGS. 2 and 3, the power module according to Embodiment 1 includes a heat dissipation member 1, an insulation member 10, a conductive pattern 100 on the positive electrode side as a first conductive pattern, a conductive pattern 200 on the negative electrode side as a second conductive pattern, a bonding member 20, the first to fifth IGBTs (111, 112, 113, 114, 115), the first to fifth freewheeling diodes (121, 122, 123, 124, 125), a sealing member 30, and wires 40. The insulation member 10 includes a main surface 10a. The positive electrode 101 is connected to the conductive pattern 100 on the positive electrode side. The negative electrode 201 is connected to the conductive pattern 200 on the negative electrode side.

In the following description, a plane parallel to the main surface 10a of the insulation member 10 is defined as the XY plane, and the direction orthogonal to the main surface 10a is defined as the Z direction. In the arrangement direction of the first to fifth IGBTs (111, 112, 113, 114, 115), the direction from the first IGBT 111 to the fifth IGBT 115 is defined as the +X direction. The X direction corresponds to a first direction, and the Y direction corresponds to a second direction. In the present specification, when indicating directions and distinguishing between positive and negative, the positive and negative symbols are added, for example, “the +X direction” and “the −X direction”. When directions are indicated without distinguishing between positive and negative, it is simply described as “the X direction”. In other words, within this specification, a direction described simply as “the X direction” shall be understood to include both “the +X direction” and “the −X direction”. The same applies to the Y direction and the Z direction.

The heat dissipation member 1 shown in FIG. 3 dissipates heat generated in the first to fifth IGBTs (111, 112, 113, 114, 115) and the first to fifth freewheeling diodes (121, 122, 123, 124, 125). The heat dissipation member 1 is a heat sink made of metal, for example. Examples of the material constituting the heat sink include aluminum, copper, an alloy containing aluminum, and an alloy containing copper.

As shown in FIG. 3, the insulation member 10 is arranged on the heat dissipation member 1. The insulation member 10 electrically insulates the heat dissipation member 1 and the conductive pattern 100 on the positive electrode side. The insulation member 10 is also a member that transfers the heat of the conductive pattern 100 on the positive electrode side to the heat dissipation member 1. The insulation member 10 electrically insulates the heat dissipation member 1 and the conductive pattern 200 on the negative electrode side. The insulation member 10 transfers the heat of the conductive pattern 200 on the negative electrode side to the heat dissipation member 1.

The insulation member 10 is, for example, an insulation sheet or an insulation plate. The insulation sheet may be constituted by, for example, an epoxy resin filled with a filler such as silica (SiO₂), alumina (Al₂O₃), or boron nitride (BN). The insulation plate may be a ceramic such as alumina (Al₂O₃) and aluminum nitride (AlN).

As shown in FIG. 3, the conductive pattern 100 on the positive electrode side and the conductive pattern 200 on the negative electrode side are arranged on the main surface 10a of the insulation member 10. That is, the conductive pattern 100 on the positive electrode side is arranged in contact with the main surface 10a. The conductive pattern 200 on the negative electrode side is arranged in contact with the main surface 10a. As shown in FIG. 2, the conductive pattern 100 on the positive electrode side and the conductive pattern 200 on the negative electrode side are arranged apart in the Y direction such that they are electrically insulated from each other. The conductive pattern 100 on the positive electrode side and the conductive pattern 200 on the negative electrode side are plate-shaped members and are made of metal. Examples of the material constituting the conductive pattern 100 on the positive electrode side and the conductive pattern 200 on the negative electrode side include copper, aluminum, an alloy containing copper, and an alloy containing aluminum.

As shown in FIG. 2, the positive electrode 101 is connected to the conductive pattern 100 on the positive electrode side. The negative electrode 201 is connected to the conductive pattern 200 on the negative electrode side. The positive electrode 101 and the negative electrode 201 are exposed to the outside from the sealing member 30 not shown in FIG. 2. That is, the positive electrode 101 is a first external terminal for electrically connecting the power module to an external device. The negative electrode 201 is a second external terminal for electrically connecting the power module to an external device.

In the present embodiment, the positive electrode 101 as the first external terminal is a member independent of the conductive pattern 100 on the positive electrode side. However, the positive electrode 101 may be integrally formed as a part of the conductive pattern 100 on the positive electrode side. That is, a part of the conductive pattern 100 on the positive electrode side exposed from the sealing member 30 may be the positive electrode 101. Similarly, the negative electrode 201 may be integrally formed as a part of the conductive pattern 200 on the negative electrode side.

As shown in FIG. 2, on the conductive pattern 100 on the positive electrode side, the first to fifth IGBTs (111, 112, 113, 114, 115) and the first to fifth freewheeling diodes (121, 122, 123, 124, 125) are arranged side by side in the X direction. The first IGBT 111 and the first freewheeling diode 121 are arranged adjacent to each other in such a manner as to form a pair, and constitute one power conversion semiconductor element. Similarly, the second to fifth IGBTs (112, 113, 114, 115) and the second to fifth freewheeling diodes (122, 123, 124, 125) are respectively arranged adjacent to each other to form pairs of an IGBT and a freewheeling diode. Thus, the first to fifth IGBTs (111, 112, 113, 114, 115) and the first to fifth freewheeling diodes (121, 122, 123, 124, 125) constitute a first power conversion semiconductor element group.

As shown in FIG. 3, the first IGBT 111 is arranged on the conductive pattern 100 on the positive electrode side via the bonding member 20. The bonding member 20 is made of solder or a sintered material, for example. In the first IGBT 111, a surface on the side in contact with the bonding member 20 (in the −Z direction) is a collector electrode 111c, and a surface on the opposite side thereof is an emitter electrode 111e (in the +Z direction). The second to fifth IGBTs (112, 113, 114, 115) and the first to fifth freewheeling diodes (121, 122, 123, 124, 125) are also arranged on the conductive pattern 100 on the positive electrode side via the bonding member 20, similarly to the first IGBT 111. In the first to fifth freewheeling diodes (121, 122, 123, 124, 125), the surface in the −Z direction is a cathode, and the surface in the +Z direction is an anode.

As shown in FIG. 2, the emitter electrode 111e of the first IGBT 111 and the conductive pattern 200 on the negative electrode side are connected by one of the wires 40. Similarly, the second to fifth IGBTs (112, 113, 114, 115) are connected to the conductive pattern 200 on the negative electrode side by their respective wires 40 connected to their respective emitter electrodes. The first to fifth freewheeling diodes (121, 122, 123, 124, 125) are connected to the conductive pattern 200 on the negative electrode side by their respective wires 40 connected to their respective anodes. The wires 40 are, for example, a bonding wire or a ribbon wire. Examples of the material constituting the bonding wire or the ribbon wire include copper, gold, platinum, aluminum, and an alloy containing at least one of these.

As shown in FIG. 2, a slit 202 is formed in the conductive pattern 200 on the negative electrode side. The slit 202 includes a second direction slit 202a formed to extend in the Y direction and a first direction slit 202b formed to extend in the X direction. The second direction slit 202a is formed to extend in the Y direction such that it partitions, in the conductive pattern 200 on the negative electrode side, the region to which the wires 40 are connected and the negative electrode 201. The first direction slit 202b is formed to extend from the end portion of the second direction slit 202a on the +Y direction side to the +X direction side.

A method of forming the slit 202 in the conductive pattern 200 on the negative electrode side is not particularly limited. The slit 202 may be formed by, for example, machining the conductive pattern 200 on the negative electrode side. A specific example of the machining is milling. When the slit 202 is formed in the conductive pattern 200 on the negative electrode side by the milling, the shape of the slit 202 depends on the shape of an end mill. To be specific, as shown in FIG. 4, the end portion of the second direction slit 202a on the +Y direction side and the end portion of the first direction slit 202b on the +X direction side may have a rounded shape.

The slit 202 is provided to lengthen the current path lengths from the first to fifth IGBTs (111, 112, 113, 114, 115) to the negative electrode 201. In the case where the slit 202 is formed in the conductive pattern 200 on the negative electrode side, the current path from each of the first to fifth IGBTs (111, 112, 113, 114, 115) to the negative electrode 201 is extended as compared with a case where the slit 202 is not provided in the conductive pattern 200 on the negative electrode side. In particular, the current path from each of the first to third IGBTs (111, 112, 113) to the negative electrode 201 has a longer portion extended by the slit 202 than the current path from the fourth IGBT 114 or the fifth IGBT 115 to the negative electrode 201. By forming the slit 202 in the conductive pattern 200 on the negative electrode side, the length of the current path from each of the first to third IGBTs (111, 112, 113) to the negative electrode 201 can be made close to the length of the current path from the fourth IGBT 114 to the negative electrode 201 and the length of the current path from the fifth IGBT 115 to the negative electrode 201.

In this manner, by extending the current paths by the slit 202, it is possible to reduce the variation among the current path lengths from the first to fifth IGBTs (111, 112, 113, 114, 115) to the negative electrode 201. The reduction in the variation among the current path lengths contributes to the prevention of the concentration of the currents in some of the first to fifth IGBTs (111, 112, 113, 114, 115).

The variation among the current path lengths from each of the first to fifth freewheeling diodes (121, 122, 123, 124, 125) to the negative electrode 201 can also be reduced by the slit 202. The reduction in the variation among the current path lengths contributes to the prevention of the currents from concentrating on some of the first to fifth freewheeling diodes (121, 122, 123, 124, 125).

Here, the number of power conversion semiconductor elements each configured with a pair of an IGBT and a freewheeling diode is defined as N. The number of power conversion semiconductor elements connected to a first partition region 203 by their respective wires 40, among the power conversion semiconductor elements constituting the power conversion semiconductor element group, is defined as M. In this case, it is preferable that the relationship between N and M satisfies M>N/2. By configuring to satisfy M>N/2, the variation among the current path lengths can be more effectively reduced by the slit 202. As shown in FIG. 2, in the present embodiment, N=5 and M=3, and the relationship of M>N/2 is satisfied.

As shown in FIG. 2, the conductive pattern 200 on the negative electrode side includes the first partition region 203 and a second partition region 204. The first partition region 203 is the region partitioned by the slit 202. The second partition region 204 is the region adjacent to the first partition region 203. In the present embodiment, the second partition region 204 is adjacent to the first partition region 203 in the +X direction. The dash-dot-dot line shown in FIG. 2 indicates the boundary between the first partition region 203 and the second partition region 204. The wire 40 connected to the first IGBT 111, the wire 40 connected to the first freewheeling diode 121, the wire 40 connected to the second IGBT 112, the wire 40 connected to the second freewheeling diode 122, the wire 40 connected to the third IGBT 113, and the wire 40 connected to the third freewheeling diode 123 are connected to the first partition region 203. The wire 40 connected to the fourth IGBT 114, the wire 40 connected to the fourth freewheeling diode 124, the wire 40 connected to the fifth IGBT 115, and the wire 40 connected to the fifth freewheeling diode 125 are connected to the second partition region 204.

As shown in FIG. 3, the sealing member 30 is arranged on the main surface 10a of the insulation member 10. The sealing member 30 covers members other than the positive electrode 101 (the first external terminal) and the negative electrode 201 (the second external terminal). The sealing member 30 is, for example, a molding resin. The molding resin may be one formed of, for example, an epoxy resin filled with a filler such as silica (SiO₂), alumina (Al₂O₃), and boron nitride (BN). The sealing member 30 may also be filled into the slit 202. The slit 202 may not be filled with the sealing member 30, and a cavity may be formed in the slit 202.

The sealing member 30 is made of a material having good insulation and thermal conductivity. However, in general, the insulation material used for the sealing member 30 has a thermal conductivity significantly inferior to that of metal. For example, thermal conductivity of aluminum is on the order of 200 W/mK. In contrast, thermal conductivity of a typical molding resin is about several W/mK.

The dissipation of heat generated in the power conversion semiconductor elements will be described with reference to FIG. 2. In the following, the dissipation of heat generated in the first to fifth IGBTs (111, 112, 113, 114, 115) will be described for the case where the current flows from the positive electrode 101 to the negative electrode 201. The description of heat dissipation regarding the heat generated in the first to fifth freewheeling diodes (121, 122, 123, 124, 125) for the case where the current flows from the negative electrode 201 to the positive electrode 101 is the same as the description of heat dissipation using, as an example, the IGBTs among the power conversion semiconductor elements, and thus the description thereof will be omitted.

When the current flows in the direction from the collector electrode to the emitter electrode of each of the first to fifth IGBTs (111, 112, 113, 114, 115), each of the first to fifth IGBTs (111, 112, 113, 114, 115) generates heat. Some of the heat generated in the first to fifth IGBTs (111, 112, 113, 114, 115) is transferred to the heat dissipation member 1 via the bonding member 20 and the insulation member 10. The heat transferred to the heat dissipation member 1 is dissipated from the heat dissipation member 1. Some of the heat generated in the first to fifth IGBTs (111, 112, 113, 114, 115) is transferred to connection portions between their respective wires 40 and the conductive pattern 200 on the negative electrode side via their respective wires 40. The heat transferred to the connection portions between the respective wires 40 and the conductive pattern 200 on the negative electrode side is transferred in the X direction and the Y direction as well as in the −Z direction within the conductive pattern 200 on the negative electrode side.

As described above, the sealing member 30 filled in the slit 202 is less likely to transfer heat than the metal constituting the conductive pattern 200 on the negative electrode side. Also, air is less likely to conduct heat than metal. Therefore, in the case where the slit 202 is provided in the conductive pattern 200 on the negative electrode side, the heat transferred from the first to third IGBTs (111, 112, 113) to the conductive pattern 200 on the negative electrode side via their respective wires 40 is less likely to be transferred to the region on the +Y direction side partitioned by the slit 202.

Therefore, in the case where the slit 202 is provided in the conductive pattern 200 on the negative electrode side and the width A in the Y direction of the first partition region 203 is not sufficiently secured, the temperature of the first partition region 203 is higher than the temperature of the second partition region 204. That is, in the case where the width A is not sufficiently secured, the variation in temperature distribution in the conductive pattern 200 on the negative electrode side becomes large.

Therefore, the first to third IGBTs (111, 112, 113) are less likely to be cooled by heat conduction to the conductive pattern 200 on the negative electrode side via their respective wires 40 than the fourth and fifth IGBTs (114, 115). Therefore, in the case where the width A is not sufficiently secured, the temperature of the first to third IGBTs (111, 112, 113) is likely to increase.

Also, in the case where the slit 202 is provided in the conductive pattern 200 on the negative electrode side, the heat transferred from the first IGBT 111 to the conductive pattern 200 on the negative electrode side via its wire 40 is not easily transferred to the region on the −X direction side partitioned by the slit 202. Therefore, the first IGBT 111 is not easily cooled by the heat conduction to the conductive pattern 200 on the negative electrode side via its wire 40 and thus the temperature is likely to increase when compared with the second IGBT 112 and the third IGBT 113.

Meanwhile, it is known that a semiconductor element made of silicon (Si) has a property that the current flows more easily as the temperature of the element is higher. Therefore, for example, in the case where the first to fifth IGBTs (111, 112, 113, 114, 115) are IGBTs made of Si, if the width A is not sufficiently secured, the probability that the currents concentrate on the first IGBT 111 increases.

In general, the electrical resistance of a metal increases as temperature increases. Therefore, in the case where the width A is not sufficiently secured and the variation in temperature distribution in the conductive pattern 200 on the negative electrode side is large, the variation among impedances from the first to fifth IGBTs (111, 112, 113, 114, 115) to the negative electrode 201 becomes large. Due to such variation among the impedances, the magnitudes of the currents flowing through the first to fifth IGBTs (111, 112, 113, 114, 115) may vary. As a result of the variation among the magnitudes of the currents flowing through the first to fifth IGBTs (111, 112, 113, 114, 115), the currents may concentrate on some of the IGBTs.

On the other hand, in the power module according to the present embodiment, the width A is determined such that it satisfies the relationship of A≥B×M/N.

The power module according to the present embodiment shall have a configuration in which the width A is sufficiently secured in accordance with the ratio of N and M. Also, the first partition region 203 in which the width A is sufficiently secured is in contact with the main surface 10a. This configuration can reduce the variation in the temperature distribution in the conductive pattern 200 on the negative electrode side. In addition, the variation among the impedances from the power conversion semiconductor elements to the negative electrode 201 can be reduced. As a result, the variation among the magnitudes of the currents flowing through each of the power conversion semiconductor elements is reduced, and thus, the currents are suppressed from concentrating on some of the power conversion semiconductor elements. Thus, the reliability of the power module is improved.

If the width in the Y direction of the region on the +Y direction side of the first direction slit 202b in the conductive pattern 200 on the negative electrode side is narrowed, this region may be easily deformed. This may cause a problem that it is difficult to manufacture the power module or a problem that the reliability of the power module is lowered.

Therefore, in the power module according to the present embodiment, the width A may be determined such that it satisfies the relationship of A≤B×(N−0.5)/N as well as the relationship of A≥B×M/N. That is, the width A may be determined such that it satisfies B×M/N≤A≤B×(N−0.5)/N. By configuring the power module in this manner, the reliability of the power module is further improved.

Further, a configuration for reducing the variation among the magnitudes of the currents flowing through each of the power conversion semiconductor elements with higher accuracy will be described. In the following description, a case where the current flows from the positive electrode 101 to the negative electrode 201, in other words, where the currents flow through the IGBTs among the power conversion semiconductor elements will be used as an example. The case where the currents flow through the freewheeling diodes among the power conversion semiconductor elements will be omitted from the description here but can be described in the same manner as in the case where the IGBTs are exemplified.

In FIG. 2, the five dashed-line rectangles shown in the conductive pattern 200 on the negative electrode side tentatively represent regions which can be utilized to cool the respective wires 40. As shown in FIG. 2, the width in the X direction of the first partition region 203 is defined as C. The sum of the width C and the width in the X direction of the second partition region 204 is defined as D.

In this case, if the width C is determined such that it satisfies the relationship of C=D×[(M×B/A)/{N−M×(1−B/A)}], the areas of the regions which can be used for cooling the respective wires 40 connected to the first to fifth IGBTs (111, 112, 113, 114, 115) can be equally secured. As a result, it is possible to reduce the variation among the temperatures of the respective wires 40 connected to the first to fifth IGBTs (111, 112, 113, 114, 115). Thus, the variation among the magnitudes of the currents flowing through the first to fifth IGBTs (111, 112, 113, 114, 115) can be reduced with higher accuracy.

Also, in the power module according to the present embodiment, when the area of the first partition region 203 is defined as S1 and the area of the second partition region 204 is defined as S2, the size of S1 may be determined such that it satisfies the relationship of S1≥S2×{M/(N−M)}. By defining in this manner, the size of the area S1 of the first partition region 203 is sufficiently secured, and thus, it is possible to reduce the variation in the temperature distribution in the conductive pattern 200 on the negative electrode side. In addition, the variation among the impedances from the power conversion semiconductor elements to the negative electrode 201 can be reduced. As a result, the variation among the magnitudes of the currents flowing through each of the power conversion semiconductor elements is reduced, and thus, the currents are suppressed from concentrating on some of the power conversion semiconductor elements. Thus, the reliability of the power module is improved.

In the case where the size of S1 satisfies the relationship of S1≥S2×{M/(N−M)}, the width A may be determined such that it satisfies the relationship of A≤B×(N−0.5)/N. By configuring the power module in this manner, the reliability of the power module is further improved. Since S1=A×C, the size of S1 may be determined such that it satisfies S2×{M/(N−M)}≤S1≤B×C×(N−0.5)/N.

### Modification

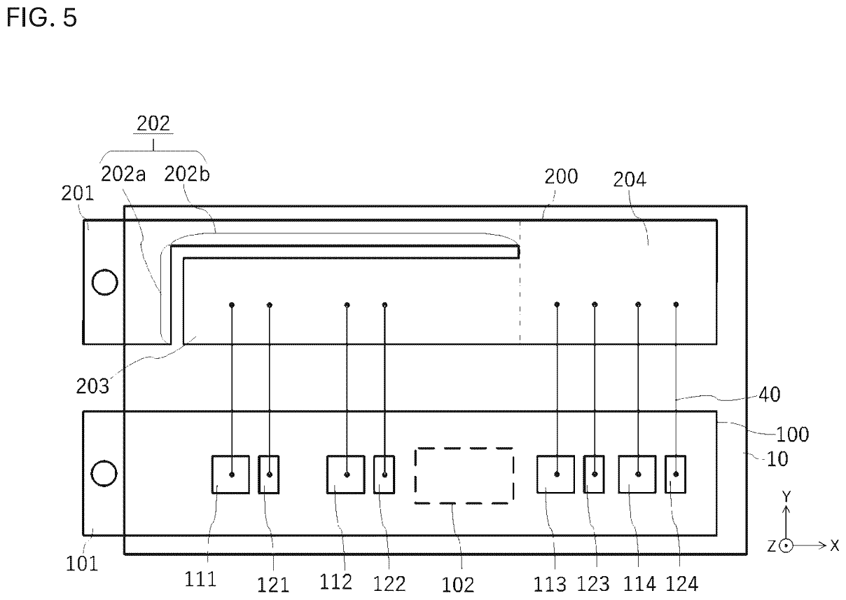

A modification of Embodiment 1 will be described with reference to FIG. 5. The power module according to the modification is different from the power module according to Embodiment 1 in that the number of the power conversion semiconductor elements constituting the first power conversion semiconductor element group is four. Further, the power module according to the modification is different from the power module according to Embodiment 1 in that an unmounted region 102 is provided in the conductive pattern 100 on the positive electrode side. In other respects, the configuration of the power module according to the modification is common to the configuration of the power module according to Embodiment 1.

Therefore, the following description will focus mainly on the differences from the power module according to Embodiment 1. The description of the common points will be omitted or simplified. The same symbols are given to the configurations which are common to the power module according to Embodiment 1.

As shown in FIG. 5, in the modification, four power conversion semiconductor elements each including a pair of an IGBT and a freewheeling diode are connected in parallel. That is, in the modification, a case is exemplified in which the current rating is increased four times compared to the case of one power conversion semiconductor element. In the modification, N=4 and M=2, so that the relationship of M>N/2 is not satisfied.

As shown in FIG. 5, the first IGBT 111 is connected to the first partition region 203 by its wire 40. The second IGBT 112 is connected to the first partition region 203 by its wire 40. The first freewheeling diode 121 is connected to the first partition region 203 by its wire 40. The second freewheeling diode 122 is connected to the first partition region 203 by its wire 40. The third IGBT 113 is connected to the second partition region 204 by its wire 40. The fourth IGBT 114 is connected to the second partition region 204 by its wire 40. The third freewheeling diode 123 is connected to the second partition region 204 by its wire 40. The fourth freewheeling diode 124 is connected to the second partition region 204 by its wire 40.

In FIG. 5, the dashed-lined rectangle shown in the conductive pattern 100 on the positive electrode side indicates the unmounted region 102. No power conversion semiconductor element is placed on the unmounted region 102. The size of the unmounted region 102 is a size in which at least one power conversion semiconductor element can be accommodated. That is, a group of the first and second IGBTs (111, 112) and the first and second freewheeling diodes (121, 122) and a group of the third and fourth IGBTs (113, 114) and the third and fourth freewheeling diodes (123, 124) are arranged with a space in which at least one power conversion semiconductor element can be accommodated.

As shown in FIG. 5, the unmounted region 102 faces the first partition region 203 in the Y direction (the second direction). In the present specification, the case where the unmounted region 102 and the first partition region 203 face each other means the case where the unmounted region 102 overlaps the first partition region 203 in the Y direction (the second direction).

In the case where the unmounted region 102 is provided in the conductive pattern 100 on the positive electrode side, even if the relationship of M>N/2 is not satisfied, the impedances from the first and second IGBTs (111, 112) and the first and second freewheeling diodes (121, 122) to the negative electrode 201 can be brought close to the impedances from the third and fourth IGBTs (113, 114) and the third and fourth freewheeling diodes (123, 124) to the negative electrode 201.

As a result, compared to the case where the unmounted region 102 is not provided in the conductive pattern 100 on the positive electrode side, it is possible to reduce the variation among the magnitudes of the currents flowing through each of the power conversion semiconductor elements, and thus, the currents are suppressed from being concentrated on some of the power conversion semiconductor elements. Thus, the reliability of the power module is further improved.

### Embodiment 2

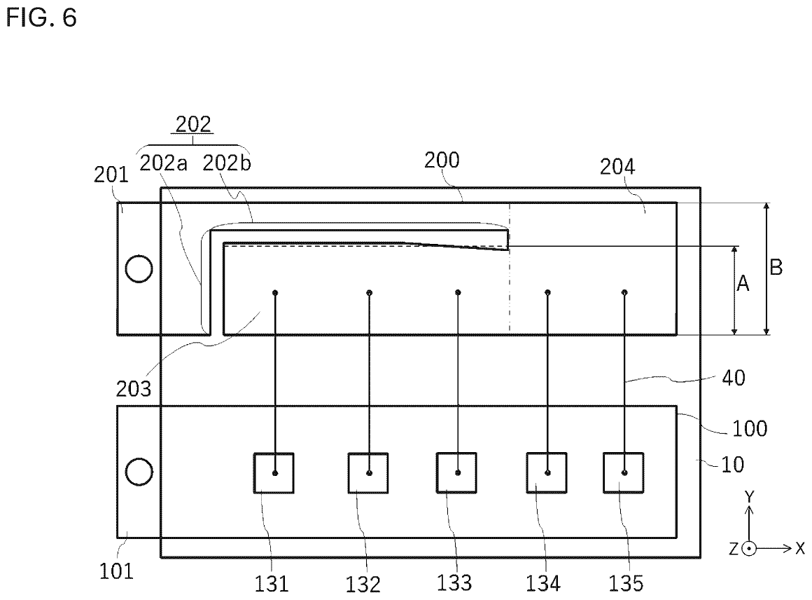

Embodiment 2 will be described with reference to FIG. 6. The power module according to Embodiment 2 is different from the power module according to Embodiment 1 in that the power conversion semiconductor elements constituting the first power conversion semiconductor element group are MOSFETs. In addition, the shape of the first partition region 203 of the power module according to Embodiment 2 is different from that of the power module according to Embodiment 1. In other respects, the configuration of the power module according to Embodiment 2 is common to the configuration of the power module according to Embodiment 1.

Therefore, the following description will focus mainly on the differences from the power module according to Embodiment 1. The description of the common points will be omitted or simplified. The same symbols are given to the configurations which are common to the power module according to Embodiment 1. Embodiment 2 will be described with reference, as appropriate, to the XYZ coordinate system defined in the same manner as in Embodiment 1.

As shown in FIG. 6, in the power module according to Embodiment 2, first to fifth MOSFETs (131, 132, 133, 134, 135) are arranged side by side in the X direction on the conductive pattern 100 on the positive electrode side. The first to fifth MOSFETs (131, 132, 133, 134, 135) constitute the first power conversion semiconductor element group.

As shown in FIG. 6, the first MOSFET 131 is connected to the first partition region 203 by its wire 40. The second MOSFET 132 is connected to the first partition region 203 by its wire 40. The third MOSFET 133 is connected to the first partition region 203 by its wire 40. The fourth MOSFET 134 is connected to the second partition region 204 by its wire 40. The fifth MOSFET 135 is connected to the second partition region 204 by its wire 40.

As shown in FIG. 6, in the power module according to Embodiment 2, the width in the Y direction of the first partition region 203 is narrower at the +X side end portion than at the −X side end portion. In the case where the width of the +X side end portion of the first partition region 203 is narrowed in this manner, the impedances from the first to third MOSFETs (131, 132, 133) to the negative electrode 201 can be brought close to the impedances from the fourth and fifth MOSFETs (134, 135) to the negative electrode 201.

As a result, compared to the case where the width of the +X side end portion of the first partition region 203 is not narrowed, it is possible to reduce the variation among the magnitudes of the currents flowing through each of the power conversion semiconductor elements, and thus, the reliability of the power module is further improved.

It can also be said that, in the power module according to Embodiment 2, the width in the Y direction (the second direction) of the first partition region 203 on the side farthest from the second partition region 204 is wider than the width in the Y direction (the second direction) of the first partition region 203 on the side closest to the second partition region 204. In the case where the first partition region 203 is formed in such a shape, the first MOSFET 131, where the temperature is particularly likely to increase, can be efficiently cooled, and thus, the reliability of the power module is improved.

Also in the power module according to Embodiment 2, the width A is determined such that it satisfies the relationship of A≥B×M/N as in Embodiment 1. Here, the width A is the average width of the first partition region 203, as shown by the dashed line in FIG. 6.

Also in the power module according to Embodiment 2, it is preferable that M>N/2 is satisfied.

Also in the power module according to Embodiment 2, the width A may be determined such that it satisfies B×M/N≤A≤B×(N−0.5)/N.

Also in the power module according to Embodiment 2, when the area of the first partition region 203 is defined as S1 and the area of the second partition region 204 is defined as S2, the size of S1 may be determined such that it satisfies the relationship of S1≥S2×{M/(N−M)}.

Also in the power module according to Embodiment 2, in the case where the size of S1 satisfies the relationship of S1≥S2×{M/(N−M)}, the width A may be determined such that it satisfies the relationship of A≤B×(N−0.5)/N. That is, the size of S1 may be determined such that it satisfies S2×{M/(N−M)}≤S1≤B×C×(N−0.5)/N.

The configuration shown in the modification of Embodiment 1 can be similarly applied to the power module according to Embodiment 2.

### Embodiment 3

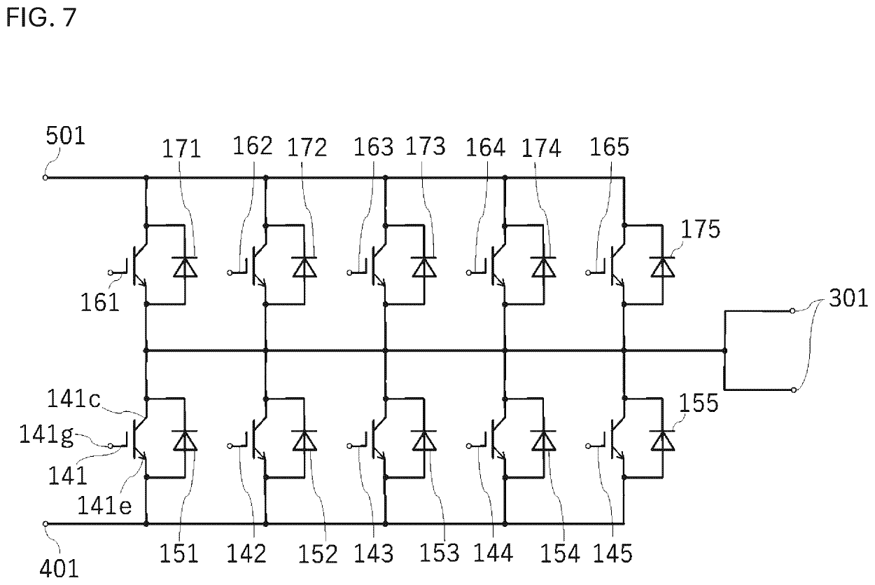

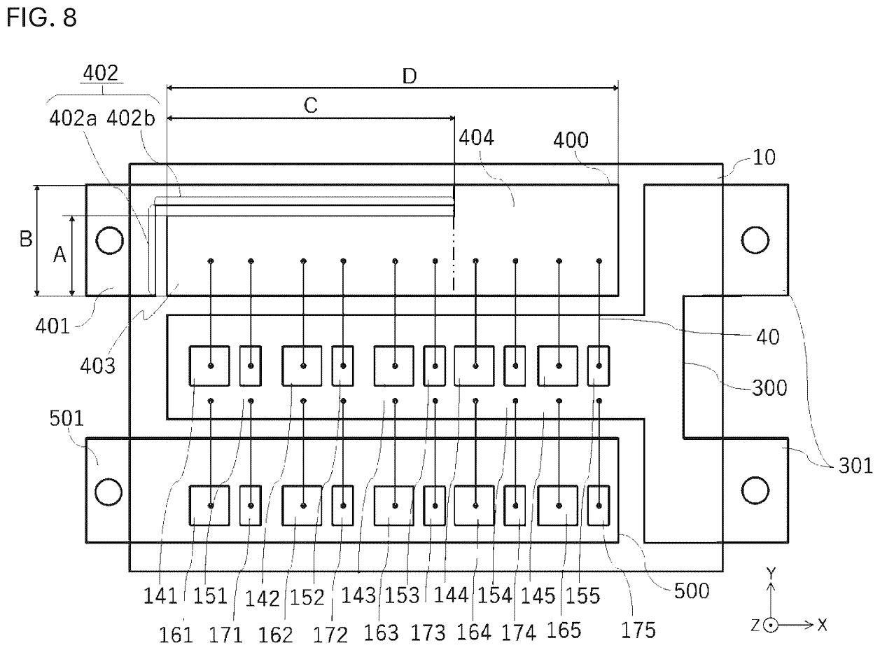

Embodiment 3 will be described with reference to FIGS. 7 and 8. Embodiment 3 is an example of a case where the invention of the present disclosure is applied to a two-level inverter circuit. Hereinafter, the differences from the power module according to Embodiment 1 will be mainly described. The description of the common points will be omitted or simplified. The same symbols are given to the configurations which are common to the power module according to Embodiment 1. Embodiment 3 will be described with reference, as appropriate, to the XYZ coordinate system defined in the same manner as in Embodiment 1.

FIG. 7 is a circuit diagram of a power module according to Embodiment 3 of the present disclosure. FIG. 7 shows an output electrode 301 of intermediate potential, a negative electrode 401 of low potential, a positive electrode 501 of high potential, low-potential side IGBTs (141, 142, 143, 144, 145) on first to fifth legs, low-potential side freewheeling diodes (151, 152, 153, 154, 155) on the first to fifth legs, high-potential side IGBTs (161, 162, 163, 164, 165) on the first to fifth legs, and high-potential side freewheeling diodes (171, 172, 173, 174, 175) on the first to fifth legs.

Here, in the present embodiment, the case where two output electrodes 301 are provided is exemplified. However, there may be only one output electrode 301. More than two output electrodes 301 may be provided.

The low-potential side IGBT 141 on the first leg can be switched in conductivity between a collector electrode 141c and an emitter electrode 141e by applying voltage between a gate electrode 141g and the emitter electrode 141e. When a positive voltage is applied between the gate electrode 141g and the emitter electrode 141e, the state between the collector electrode 141c and the emitter electrode 141e becomes a state of low resistance. Then, the current flows in the direction from the collector electrode 141c to the emitter electrode 141e. On the other hand, when a voltage equal to or lower than 0 V is applied between the gate electrode 141g and the emitter electrode 141e, the state between the collector electrode 141c and the emitter electrode 141e becomes a state of high resistance. Then, the current between the collector electrode 141c and the emitter electrode 141e is blocked. The low-potential side IGBTs (142, 143, 144, 145) on the second to fifth legs and the high-potential side IGBTs (161, 162, 163, 164, 165) on the first to fifth legs each also have the same function as the low-potential side IGBT 141 on the first leg.

In the present Embodiment, as in Embodiment 1, the number of power conversion semiconductor elements connected in parallel to the low-potential side and the number of power conversion semiconductor elements connected in parallel to the high-potential side are set as appropriate according to the current rating of the power module. In the present embodiment, a case is exemplified where the current rating is increased five times compared to the case where one power conversion semiconductor element is arranged on each of the low-potential side and the high-potential side.

The low-potential side freewheeling diode 151 on the first leg is connected in anti-parallel with the low-potential side IGBT 141 on the first leg. The low-potential side freewheeling diode 151 on the first leg becomes the conductive path when the current flows in the direction from the emitter electrode 141e to the collector electrode 141c, of the low-potential side IGBT 141 on the first leg. The low-potential side freewheeling diodes on the second to fifth legs (152, 153, 154, 155) and the high-potential side freewheeling diodes (171, 172, 173, 174, 175) on the first to fifth legs each also have the same function as the low-potential side freewheeling diode 151 on the first leg.

Also in the present embodiment, as in Embodiment 1, it is necessary to reduce the variation among the magnitudes of the currents flowing through each of the low-potential side IGBTs (141, 142, 143, 144, 145) on the first to fifth legs. Also, it is also necessary to reduce the variation among the magnitudes of the currents flowing through each of the low-potential side freewheeling diodes (151, 152, 153, 154, 155) on the first to fifth legs. Also, it is also necessary to reduce the variation among the magnitudes of the currents flowing through each of the high-potential side IGBTs (161, 162, 163, 164, 165) on the first to fifth legs. Also, it is also necessary to reduce the variation among the magnitudes of the currents flowing through each of the high-potential side freewheeling diodes (171, 172, 173, 174, 175) on the first to fifth legs.

The structure of the power module according to Embodiment 3 will be described with reference to FIG. 8. The description of the materials of the members constituting the power module overlaps with the description given in Embodiment 1, and thus, it is omitted.

FIG. 8 shows a top view of the power module according to Embodiment 3. As shown in FIG. 8, the power module according to Embodiment 3 includes the insulation member 10, an intermediate potential conductive pattern 300 as the first conductive pattern, a low-potential side conductive pattern 400 as the second conductive pattern, a high-potential side conductive pattern 500 as the third conductive pattern, the low-potential side IGBTs (141, 142, 143, 144, 145) on the first to fifth legs, the low-potential side freewheeling diodes (151, 152, 153, 154, 155) on the first to fifth legs, the high-potential side IGBTs (161, 162, 163, 164, 165) on the first to fifth legs, the high-potential side freewheeling diodes (171, 172, 173, 174, 175) on the first to fifth legs, and the wires 40. The output electrodes 301 are connected to the intermediate potential conductive pattern 300. The negative electrode 401 is connected to the low-potential side conductive pattern 400. The positive electrode 501 is connected to the high-potential side conductive pattern 500.

The power module according to the present embodiment includes the sealing member 30. However, for the sake of description, the sealing member 30 is not shown in FIG. 8. The sealing member 30 covers members other than the output electrodes 301 (the first external terminals), the negative electrode 401 (the second external terminal), and the positive electrode 501 (the third external terminal). It can also be said that the output electrodes 301 (the first external terminals), the negative electrode 401 (the second external terminal), and the positive electrode 501 (the third external terminal) protrude from the sealing member 30.

The power module according to the present embodiment includes the heat dissipation member 1. However, since FIG. 8 shows a top view, the heat dissipation member 1 is not shown. The insulation member 10 is arranged on the heat dissipation member 1.

In the power module according to the present embodiment, as in Embodiment 1, a pair of an IGBT and a freewheeling diode constitutes one power conversion semiconductor element. The low-potential side IGBTs (141, 142, 143, 144, 145) on the first to fifth legs and the low-potential side freewheeling diodes (151, 152, 153, 154, 155) on the first to fifth legs constitute the first power conversion semiconductor element group. The high-potential side IGBTs (161, 162, 163, 164, 165) on the first to fifth legs and the high-potential side freewheeling diodes (171, 172, 173, 174, 175) on the first to fifth legs constitute the second power conversion semiconductor element group.

As shown in FIG. 8, a slit 402 is formed in the low-potential side conductive pattern 400. The slit 402 includes a first direction slit 402a formed in the Y direction and a second direction slit 402b formed in the X direction.

As shown in FIG. 8, the low-potential side conductive pattern 400 includes a first partition region 403 and a second partition region 404. The first partition region 403 is a region partitioned by the slit 402. The second partition region 404 is the region adjacent to the first partition region 403. In the present embodiment, the second partition region 404 is adjacent to the first partition region 403 in the +X direction. The dash-dot-dot line shown in FIG. 8 indicates the boundary between the first partition region 403 and the second partition region 404. The wire 40 connected to the low-potential side IGBT 141 on the first leg, the wire 40 connected to the low-potential side freewheeling diode 151 on the first leg, the wire 40 connected to the low-potential side IGBT 142 on the second leg, the wire 40 connected to the low-potential side freewheeling diode 152 on the second leg, the wire 40 connected to the low-potential side IGBT 143 on the third leg, and the wire 40 connected to the low-potential side freewheeling diode 153 on the third leg are connected to the first partition region 403. The wire 40 connected to the low-potential side IGBT 144 on the fourth leg, the wire 40 connected to the low-potential side freewheeling diode 154 on the fourth leg, the wire 40 connected to the low-potential side IGBT 145 on the fifth leg, and the wire 40 connected to the low-potential side freewheeling diode 155 on the fifth leg are connected to the second partition region 404.

Since the function and effect of the slit 402 is the same as the function and effect of the slit 202 in Embodiment 1, a detailed description thereof will be omitted. With the slit 402 formed in the low-potential side conductive pattern 400, the variation among the current path lengths from each of the low-potential side IGBTs (141, 142, 143, 144, 145) on the first to fifth legs to the negative electrode 401 is reduced. Also, the variation among the current path lengths from each of the low-potential side freewheeling diodes (151, 152, 153, 154, 155) on the first to fifth legs to the negative electrode 401 is reduced by the slit 402.

In the power module according to the present embodiment, when the number of the power conversion semiconductor elements constituting the first power conversion semiconductor element group is defined as N and the number of the power conversion semiconductor elements connected to the first partition region 403 by their respective wires 40 among the power conversion semiconductor elements constituting the first power conversion semiconductor element group is defined as M, the width A is determined such that it satisfies the relationship of A≥B×M/N.

The power module according to the present embodiment is configured such that the width A is sufficiently secured in accordance with the ratio of N and M. This configuration can reduce the variation in the temperature distribution in the low-potential side conductive pattern 400. In addition, the variation among the impedances from the power conversion semiconductor elements to the negative electrode 401 can be reduced. As a result, the variation among the magnitudes of the currents flowing through each of the power conversion semiconductor elements is reduced, and thus, the currents are suppressed from concentrating on some of the power conversion semiconductor elements. Thus, the reliability of the power module is improved.

As shown in FIG. 8, the width in the X direction of the first partition region 403 is defined as C. The sum of the width C and the width in the X direction of the second partition region 404 is defined as D. In this case, if the width C is determined such that it satisfies the relationship of C=D×[(M×B/A)/{N−M×(1−B/A)}], the areas of the regions which can be used for cooling the respective wires 40 connected to the low-potential side IGBTs (141, 142, 143, 144, 145) on the first to fifth legs can be equally secured. As a result, it is possible to reduce the variation among the temperatures of the respective wires 40 connected to the low-potential side IGBTs (141, 142, 143, 144, 145) on the first to fifth legs. Thus, the variation among the magnitudes of the currents flowing through the low-potential side IGBTs (141, 142, 143, 144, 145) on the first to fifth legs can be reduced with higher accuracy. As a result, the reliability of the power module is further improved.

Also in the power module according to Embodiment 3, it is preferable that M>N/2 is satisfied.

Also in the power module according to Embodiment 3, the width A may be determined such that it satisfies B×M/N≤A≤B×(N−0.5)/N.

Also in the power module according to Embodiment 3, when the area of the first partition region 403 is defined as S1 and the area of the second partition region 404 is defined as S2, the size of S1 may be determined such that it satisfies the relationship of S1≥S2×{M/(N−M)}.

Also in the power module according to Embodiment 3, when the size of S1 satisfies the relationship of S1≥S2×{M/(N−M)}, the width A may be determined such that it satisfies the relationship of A≤B×(N−0.5)/N. That is, the size of the S1 may be determined such that it satisfies S2×{M/(N−M)}≤S1≤B×C×(N−0.5)/N.

The configuration shown in the modification of Embodiment 1 can be similarly applied to the power module according to Embodiment 3.

Also in the power module according to Embodiment 3, similarly to Embodiment 2, the width in the Y direction of the first partition region 403 may be configured to be narrower at the +X side end portion than at the −X side end portion.

### Modification

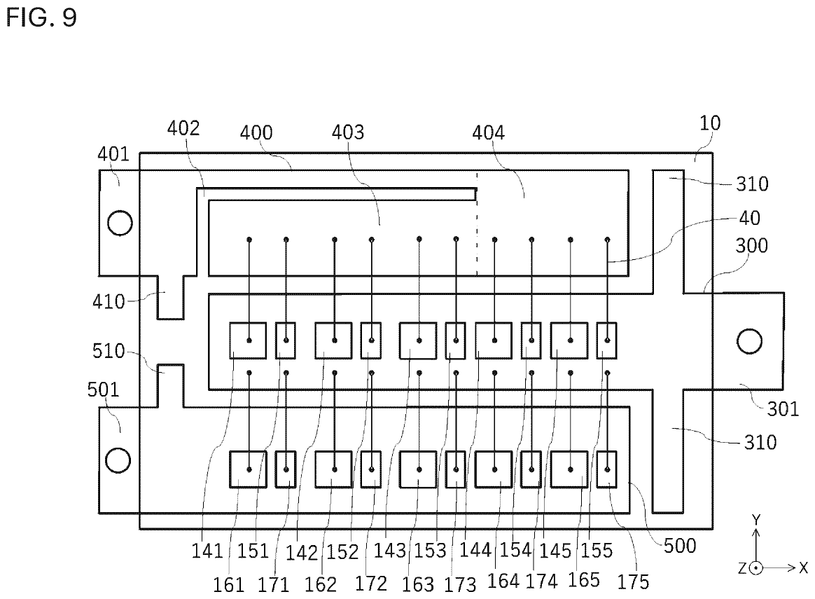

A modification of the power module according to Embodiment 3 will be described with reference to FIG. 9. FIG. 9 shows a top view of the power module according to the modification.

As shown in FIG. 9, the power module according to the modification is provided with a first enlarged pattern 310 in the intermediate potential conductive pattern 300. Further, the low-potential side conductive pattern 400 is provided with a second enlarged pattern 410. Furthermore, the high-potential side conductive pattern 500 is provided with a third enlarged pattern 510.

As shown in FIG. 9, the first enlarged pattern 310 is formed to extend in the +Y direction and the −Y direction in the region between the region in which the first power conversion semiconductor element group is arranged and the output electrode 301. The first enlarged pattern 310 is covered with the sealing member 30 (not shown). That is, the intermediate potential conductive pattern 300 (the first conductive pattern) includes the first enlarged pattern 310 between the region in which the first power conversion semiconductor element group is arranged and the output electrode 301 (the first external terminal) connected to the intermediate potential conductive pattern 300, the first enlarged pattern 310 extending in the direction different from the direction in which the output electrode 301 protrudes from the sealing member 30, into the region sealed by the sealing member 30.

Here, the function and effect of the first enlarged pattern 310 will be described. Some of the heat generated from the first power conversion semiconductor element group is transferred to the heat dissipation member 1 (not shown). Then, the transferred heat is dissipated from the heat dissipation member 1. However, some of the heat generated from the first power conversion semiconductor element group is also transferred to the output electrode 301. The heat transferred to the output electrode 301 may be transferred to an element, a device, or the like, connected to the output electrode 301. If the temperature of the output electrode 301 is high, the adverse effects may be applied to the element, the device, or the like, connected to the output electrode 301.

In the power module according to the modification, some of the heat generated from the first power conversion semiconductor element group is transferred to the first enlarged pattern 310. Therefore, the temperature of the output electrode 301 can be decreased compared to the case where the first enlarged pattern 310 is not provided in the intermediate potential conductive pattern 300. Therefore, in the power module according to the modification, the adverse effects on an element, a device, or the like, connected to the output electrode 301, due to the heat generated from the first power conversion semiconductor element group, can be prevented.

In the above description, the case where the first enlarged pattern 310 is formed to extend in two directions of the +Y direction and the −Y direction is exemplified. That is, the case where the output electrode 301 (the first external terminal) protrudes from the sealing member 30 in the first direction opposite to the protrusion direction of the negative electrode 401 (the second external terminal) and the first enlarged pattern 310 extends in two directions opposite to each other along the second direction is exemplified. However, the first enlarged pattern 310 may be formed to extend only in the +Y direction or only in the −Y direction.

As shown in FIG. 9, the second enlarged pattern 410 is formed to extend in the −Y direction in the region between the region in which the slit 402 is formed and the negative electrode 401. The second enlarged pattern 410 is covered with the sealing member 30 (not shown). That is, the low-potential side conductive pattern 400 (the second conductive pattern) includes the second enlarged pattern 410 between the region in which the slit 402 is formed and the negative electrode 401 (the second external terminal), the second enlarged pattern 410 extending in the direction different from the direction in which the negative electrode 401 protrudes from the sealing member 30, into the region sealed by the sealing member 30.

Since the function and effect of the second enlarged pattern 410 is the same as the function and effect of the first enlarged pattern 310, a detailed description thereof will be omitted. Some of the heat generated from the first power conversion semiconductor element group is transferred to the low-potential side conductive pattern 400 through the respective wires 40. Then, some of the heat transferred to the low-potential side conductive pattern 400 is transferred to the negative electrode 401. In the case where the second enlarged pattern 410 is provided in the low-potential side conductive pattern 400, it is possible to prevent the adverse effects on an element, a device, or the like, connected to the negative electrode 401, due to the heat generated from the first power conversion semiconductor element group.

As shown in FIG. 9, the third enlarged pattern 510 is formed to extend in the +Y direction in the region between the region in which the second power conversion semiconductor element group is arranged and the positive electrode 501. The third enlarged pattern 510 is covered with the sealing member 30 (not shown). That is, the high-potential side conductive pattern 500 (the third conductive pattern) includes the third enlarged pattern 510 between the region in which the second power conversion semiconductor element group is arranged and the positive electrode 501 (the third external terminal) connected to the high-potential side conductive pattern 500, the third enlarged pattern 510 extending in the direction different from the direction in which the positive electrode 501 protrudes from the sealing member 30, into the region sealed by the sealing member 30.

Since the function and effect of the third enlarged pattern 510 is the same as the function and effect of the first enlarged pattern 310, a detailed description thereof will be omitted. In the case where the third enlarged pattern 510 is provided in the high-potential side conductive pattern 500, it is possible to prevent the adverse effects on an element, a device, or the like, connected to the positive electrode 501, due to the heat generated from the second power conversion semiconductor element group.

In the above description, the case where the second enlarged pattern 410 is formed to extend in the −Y direction is exemplified. However, the second enlarged pattern 410 may be formed to extend in the +Y direction. For example, in the case where the negative electrode 401 is provided in the +Y direction of the power module, the second enlarged pattern 410 may be formed to extend in the −X direction.

In the above description, the case where the third enlarged pattern 510 is formed to extend in the +Y direction is exemplified. However, the third enlarged pattern 510 may be formed to extend in the −Y direction. For example, in the case where the positive electrode 501 is provided in the −Y direction of the power module, the third enlarged pattern 510 may be formed to extend in the −X direction.

As shown in FIG. 9, if the negative electrode 401 and the positive electrode 501 are provided in the −X direction of the power module and the second enlarged pattern 410 and the third enlarged pattern 510 are provided in the Y direction such that they face each other, the second enlarged pattern 410 and the third enlarged pattern 510 can be mounted at high density. That is, in the case where the negative electrode 401 (the second external terminal) and the positive electrode 501 (the third external terminal) protrude from the sealing member 30 in the first direction and the second enlarged pattern 410 and third enlarged pattern 510 extend oppositely in the second direction, the power module can be made smaller.

FIG. 9 shows the case where the power module includes all of the first enlarged pattern 310, the second enlarged pattern 410, and the third enlarged pattern 510. However, the power module may include one or two of the first to third enlarged patterns (310, 410, 510).

So far, the embodiments according to the present disclosure were described. The present disclosure is not limited to the above-described examples. Design changes can be made as appropriate, provided that the configurations of the present disclosure are satisfied. For example, the present disclosure allows for modification, addition, or omission of at least one configuration thereof, as well as extraction of at least one component thereof and its combination with a component of other embodiments thereof.

[Description of Symbols]

| | |
|---|---|
| 1 | heat dissipation member |
| 10 | insulation member |
| 10a | main surface |
| 20 | bonding member |
| 30 | sealing member |
| 40 | wire |
| 100 | conductive pattern on the positive electrode side |
| 101 | positive electrode |
| 102 | unmounted region |
| 111 | first IGBT |
| 111c | collector electrode |
| 111e | emitter electrode |
| 111g | gate electrode |
| 112 | second IGBT |
| 113 | third IGBT |
| 114 | fourth IGBT |
| 115 | fifth IGBT |
| 121 | first freewheeling diode |
| 122 | second freewheeling diode |
| 123 | third freewheeling diode |
| 124 | fourth freewheeling diode |
| 125 | fifth freewheeling diode |
| 131 | first MOSFET |
| 132 | second MOSFET |
| 133 | third MOSFET |
| 134 | fourth MOSFET |
| 135 | fifth MOSFET |
| 141 | low-potential side IGBT on the first leg |
| 142 | low-potential side IGBT on the second leg |
| 143 | low-potential side IGBT on the third leg |
| 144 | low-potential side IGBT on the fourth leg |
| 145 | low-potential side IGBT on the fifth leg |
| 151 | low-potential side freewheeling diode on the first leg |
| 152 | low-potential side freewheeling diode on the second |
| 153 | low-potential side freewheeling diode on the third leg |
| 154 | low-potential side freewheeling diode on the fourth |
| 155 | low-potential side freewheeling diode on the fifth leg |
| 161 | high-potential side IGBT on the first leg |
| 162 | high-potential side IGBT on the second leg |
| 163 | high-potential side IGBT on the third leg |
| 164 | high-potential side IGBT on the fourth leg |
| 165 | high-potential side IGBT on the fifth leg |
| 171 | high-potential side freewheeling diode in the first leg |
| 172 | high-potential side freewheeling diode in the second leg |
| 173 | high-potential side freewheeling diode in the third leg |
| 174 | high-potential side freewheeling diode on the fourth leg |
| 175 | high-potential side freewheeling diode on the fifth leg |
| 200 | conductive pattern on the negative electrode side |
| 201 | negative electrode |
| 202 | slit |
| 202a | second direction slit |
| 202b | first direction slit |
| 203 | first partition region |
| 204 | second partition region |
| 300 | intermediate potential pattern |
| 301 | output electrode |
| 310 | first enlarged pattern |
| 400 | low-potential side conductive pattern |
| 401 | negative electrode |
| 402 | slit |
| 402a | second direction slit |
| 402b | first direction slit |
| 403 | first partition region |
| 404 | second partition region |
| 410 | second enlarged pattern |
| 500 | high-potential side conductive pattern |
| 501 | positive electrode |
| 510 | third enlarged pattern |

1. A power module comprising:
an insulation member having a main surface;
a first conductive pattern and a second conductive pattern formed on the main surface and spaced apart from each other;
a first power conversion semiconductor element group including a plurality of power conversion semiconductor elements arranged in a first direction on the first conductive pattern; and
a plurality of wires electrically connecting their respective power conversion semiconductor elements constituting the first power conversion semiconductor element group and the second conductive pattern,
wherein a slit is formed in the second conductive pattern to lengthen a current path length from each of the power conversion semiconductor elements constituting the first power conversion semiconductor element group to a second external terminal connected to the second conductive pattern,
wherein the second conductive pattern includes:
a first partition region to which some of the plurality of wires are connected and which is partitioned by the slit; and
a second partition region to which wires other than the wires connected to the first partition region among the plurality of wires are connected and which is adjacent to the first partition region, and
wherein M>N/2 and a length of A satisfies a relationship of A≥B×M/N,
where
A is a width of the first partition region in a second direction orthogonal to the first direction,
B is a width of the second partition region in the second direction,
N is the number of the power conversion semiconductor elements constituting the first power conversion semiconductor element group, and
M is the number of the power conversion semiconductor elements connected to the first partition region by their respective wires among the power conversion semiconductor elements constituting the first power conversion semiconductor element group.

2. The power module according to claim 1, wherein a relationship of A≤B×(N−0.5)/N is satisfied.

3. The power module according to claim 1, wherein
a length of C satisfies a relationship of C=D×[(M×B/A)/{N−M×(1−B/A)}], where C is a width of the first partition region in the first direction and D is a sum of the width of the first partition region in the first direction and a width of the second partition region in the first direction.

4. A power module comprising:
an insulation member having a main surface;
a first conductive pattern and a second conductive pattern formed on the main surface and spaced apart from each other;
a first power conversion semiconductor element group including a plurality of power conversion semiconductor elements arranged in a first direction on the first conductive pattern; and
a plurality of wires electrically connecting their respective power conversion semiconductor elements constituting the first power conversion semiconductor element group and the second conductive pattern,
wherein a slit is formed in the second conductive pattern to lengthen a current path length from each of the power conversion semiconductor elements constituting the first power conversion semiconductor element group to a second external terminal connected to the second conductive pattern,
wherein the second conductive pattern includes:
a first partition region to which some of the plurality of wires are connected and which is partitioned by the slit; and
a second partition region to which wires other than the wires connected to the first partition region among the plurality of wires are connected and which is adjacent to the first partition region, and
wherein a size of S1 satisfies a relationship of S1≥S2×{M/(N−M)},
where
S1 is an area of the first partition region,
S2 is an area of the second partition region,
N is the number of the power conversion semiconductor elements constituting the first power conversion semiconductor element group, and
M is the number of the power conversion semiconductor elements connected to the first partition region by their respective wires among the power conversion semiconductor elements constituting the first power conversion semiconductor element group.

5. The power module of claim 4,
wherein the size S1 satisfies a relationship of S1≤B×C×(N−0.5)/N,
where B is a width of the second partition region in a second direction orthogonal to the first direction, and
C is a width of the first partition region in the first direction.

6. The power module according to claim 4,
wherein the first conductive pattern includes an unmounted region which has a space large enough to accommodate at least one power conversion semiconductor element but in which no power conversion semiconductor element is arranged between a power conversion semiconductor element or a power conversion semiconductor element group connected to the first partition region and a power conversion semiconductor element or a power conversion semiconductor element group connected to the second partition region among the power conversion semiconductor elements constituting the first power conversion semiconductor element group, and
wherein the unmounted region faces the first partition region in a second direction orthogonal to the first direction.

7. The power module according to claim 1, wherein a width in the second direction of the first partition region on a side farthest from the second partition region is greater than a width in the second direction of the first partition region on a side closest to the second partition region.

8. The power module according to claim 1, further comprising:
a third conductive pattern formed on the main surface and spaced apart from the first conductive pattern, on a side opposite to the second conductive pattern with respect to the first conductive pattern;
a second power conversion semiconductor element group including a plurality of power conversion semiconductor elements arranged on the third conductive pattern;
a plurality of wires electrically connecting their respective power conversion semiconductor elements constituting the second power conversion semiconductor element group and the first conductive pattern; and
a sealing member sealing the first power conversion semiconductor element group and the second power conversion semiconductor element group.

9. The power module according to claim 8, further comprising at least one first external terminal connected to the first conductive pattern.

10. The power module according to claim 9, wherein the first conductive pattern includes a first enlarged pattern between a region in which the first power conversion semiconductor element group is arranged and the at least one external terminal, the first enlarged pattern extending in a direction different from a direction in which the at least one external terminal protrudes from the sealing member, into a region sealed by the sealing member.

11. The power module according to claim 8, wherein the second conductive pattern includes a second enlarged pattern between a region in which the slit is formed and the second external terminal, the second enlarged pattern extending in a direction different from a direction in which the second external terminal protrudes from the sealing member, into the region sealed by the sealing member.

12. The power module according to claim 8, wherein the third conductive pattern includes a third enlarged pattern between a region in which the second power conversion semiconductor element group is arranged and a third external terminal connected to the third conductive pattern, the third enlarged pattern extending in a direction different from a direction in which the third external terminal protrudes from the sealing member, into the region sealed by the sealing member.

13. The power module according to claim 11,
wherein the third conductive pattern includes a third enlarged pattern between a region in which the second power conversion semiconductor element group is arranged and a third external terminal connected to the third conductive pattern, the third enlarged pattern extending in a direction different from a direction in which the third external terminal protrudes from the sealing member, into the region sealed by the sealing member, and
wherein the second external terminal and the third external terminal protrude from the sealing member in the first direction, and the second enlarged pattern and the third enlarged pattern extend facing each other in the second direction orthogonal to the first direction.

14. The power module according to claim 10, wherein the at least one external terminal protrudes from the sealing member in the first direction opposite a protrusion direction of the second external terminal, and the first enlarged pattern extends in two directions opposite to each other along the second direction orthogonal to the first direction.

15. The power module according to claim 9, wherein the at least one external terminal is integrally formed with the first conductive pattern.

16. The power module according to claim 12, wherein the third external terminal is formed integrally with the third conductive pattern.

17. The power module according to claim 1, wherein the second external terminal is integrally formed with the second conductive pattern.

18. The power module according to claim 1, wherein each of the power conversion semiconductor elements is a pair of an IGBT and a freewheeling diode.

19. The power module according to claim 5, wherein a width in the second direction of the first partition region on a side farthest from the second partition region is greater than a width in the second direction of the first partition region on a side closest to the second partition region.

20. The power module according to claim 4, further comprising:
a third conductive pattern formed on the main surface and spaced apart from the first conductive pattern, on a side opposite to the second conductive pattern with respect to the first conductive pattern;
a second power conversion semiconductor element group including a plurality of power conversion semiconductor elements arranged on the third conductive pattern;
a plurality of wires electrically connecting their respective power conversion semiconductor elements constituting the second power conversion semiconductor element group and the first conductive pattern; and
a sealing member sealing the first power conversion semiconductor element group and the second power conversion semiconductor element group.
